(19) United States
(12) Patent Application Publication
(10) Pub. No.: US 2019/0333765 A1
(43) Pub. Date: Oct. 31, 2019

(54) Semiconductor Device and Manufacturing

(71) Applicant: Infineon Technologies AG, Neubiberg (DE)

(72) Inventors: Markus Kahn, Rangersdorf (AT); Oliver Humbel, Maria Elend (AT); Ravi Keshav Joshi, Klagenfurt (AT); Philipp Sebastian Koch, Gelugor (MY); Angelika Koprowski, Klagenfurt (AT); Bernhard Leitl, Klagenfurt (AT); Christian Maier, Egg am See (AT); Gerhard Schmidt, Wernberg-Wudmath (AT); Juergen Steinbrenner, Noetsch (AT)

(21) Appl. No.: 16/395,772

(22) Filed: Apr. 26, 2019

(30) Foreign Application Priority Data
Apr. 27, 2018 (DE) 102018110240.2

(51) Int. Cl. H01L 21/02; H01L 29/66

(52) U.S. Cl. CPC H01L 21/02274; H01L 29/66053; H01L 21/02529; H01L 21/02389; H01L 21/0242; H01L 21/02378; H01L 21/02395; H01L 21/02592

(57) ABSTRACT

A method for manufacturing a high-voltage semiconductor device includes exposing a semiconductor substrate to a plasma to form a protective substance layer on the semiconductor substrate. A semiconductor device includes a semiconductor substrate and a protective substance layer on the semiconductor substrate.

### BACKGROUND

Used in power semiconductor devices, dielectric films tend to be unstable in harsh conditions, for example, when operated at high temperature or in a high humidity environment. In harsh conditions, for example, when exposed for a duration of about 100 hours to an atmosphere having 80% humidity or more, at a temperature of 80° C. or more, an oxide layer used as dielectric film absorbs water leading to electrical drift phenomena and failure of the dielectric film to resist a high voltage equal to or larger than about 80% maximum design voltage of the power semiconductor device.

Amorphous silicon carbide (a-SiC) films have been used to increase the power semiconductor resistance. When exposed to a strong electric field as is typical in the operation of the power semiconductor device, water undergoes proteolysis. As a consequence, in anodic portions of the power semiconductor device, the amorphous silicon carbide is oxidized.

### SUMMARY

In one aspect, a method for manufacturing a high-voltage semiconductor device is disclosed. The method comprises exposing a semiconductor substrate to a plasma to form a protective substance layer on the substrate. The plasma includes an inert species.

In one aspect, a semiconductor device is disclosed. The semiconductor device comprises a semiconductor substrate and a protective substance layer. The protective substance layer comprises one or more of a group consisting of: crystalline silicon carbide, amorphous silicon carbide, nitride.

Those skilled in the art will recognize additional features and advantages upon reading the following detailed description, and upon viewing the accompanying drawings.

### BRIEF DESCRIPTION OF THE FIGURES

The accompanying drawings are included to provide a further understanding of the present invention and are incorporated in and constitute a part of this specification. The drawings illustrate embodiments of the present invention and together with the description serve to explain the principles of the invention.

FIG. 1 is a flowchart that illustrates a method according to some embodiments.

FIG. 2A is a schematic diagram schematically illustrating a cross-sectional partial view of a semiconductor substrate according to some embodiments.

FIG. 2B is a schematic diagram schematically illustrating a cross-sectional partial view of a semiconductor half product according to some embodiments.

FIG. 2C is a schematic diagram schematically illustrating a cross-sectional partial view of semiconductor device according to some embodiments.

Like reference numerals designate corresponding similar parts. The elements of the drawings are not necessarily to scale relative to each other. In particular, cross-sectional views are not drawn to scale and dimensional relationships of the illustrated structures can differ from those of the illustrations. Because components of embodiments according to the present invention can be positioned in a number of different orientations, directional terminology may be used for purposes of illustration that, however, is in no way limiting, unless expressly stated to the contrary. It should be noted that views of exemplary embodiments are merely to illustrate selected features of the embodiment.

Other embodiments according to the present invention and many of the intended advantages of the present invention will be readily appreciated as they become better understood by reference to the following detailed description. It is to be understood that other embodiments may be utilized and structural or logical changes may be made without departing from the scope of the present invention. The following detailed description, therefore, is not to be taken in a limiting sense, and the scope of the present invention is defined by the appended claims.

### DETAILED DESCRIPTION

Below, embodiments, implementations and associated effects are disclosed with reference to the accompanying drawings.

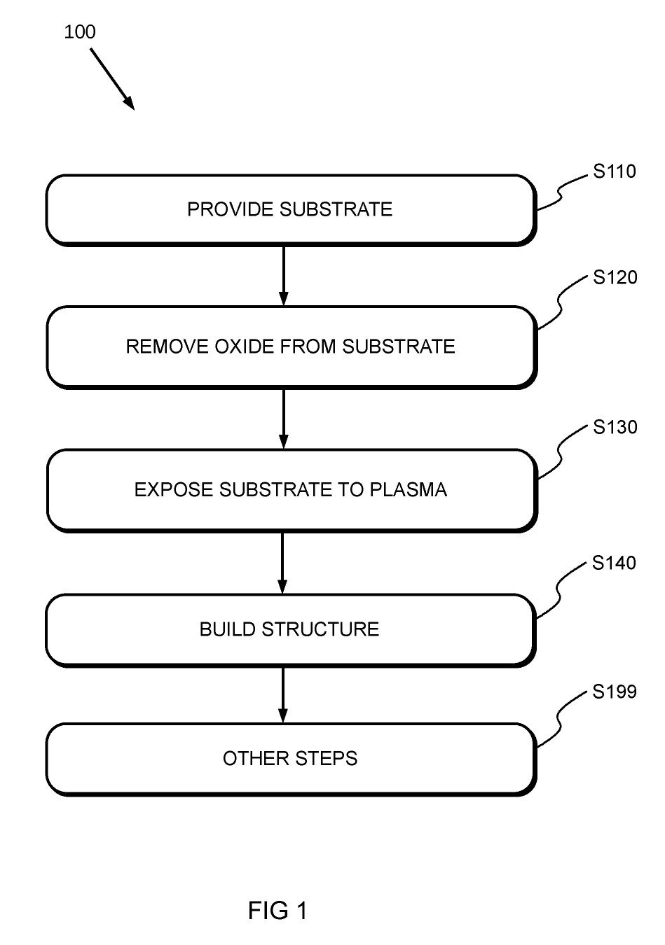

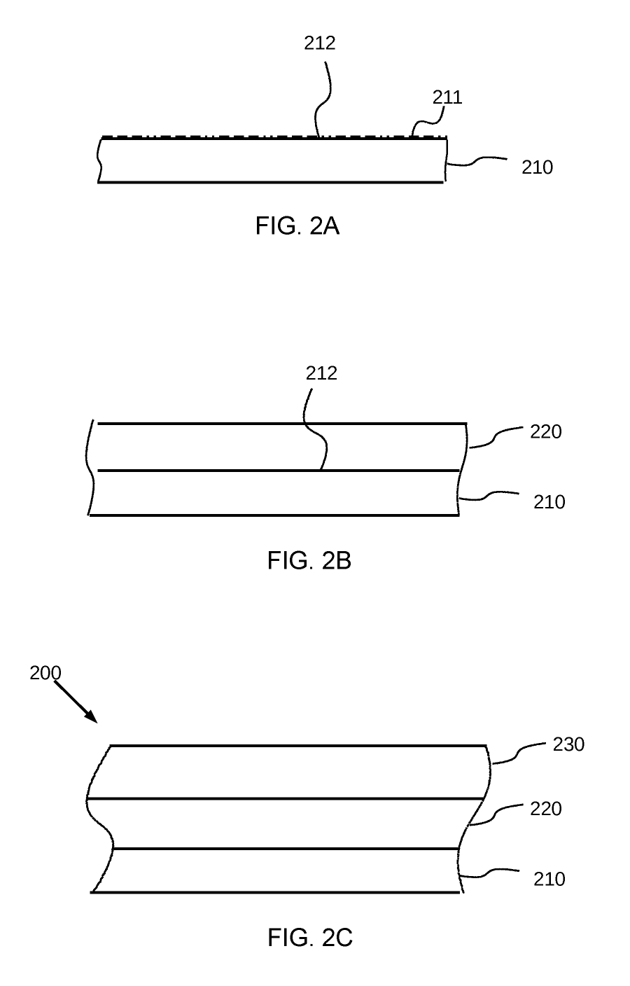

FIG. 1 is a flowchart that illustrates a method 100 according to some embodiments. Generally, the method can be used in manufacturing a high-voltage semiconductor device, for example, from a wafer. Below when explaining the method, reference will also be made to an exemplary semiconductor device 200 illustrated in FIGS. 2A, 2B and 2C. However, it should be understood, as the skilled person will readily appreciate that the method 100 can also be used to manufacture semiconductor devices that may differ from the semiconductor device 200 which is merely an exemplary embodiment.

At S110, a substrate 210 (FIG. 2A) such as a wafer is provided. For example, the substrate 210 can be crystalline. In some embodiments, material of the substrate 210 is a semiconductor. In some embodiments, the crystalline substrate 210 comprises one or more of a group of materials consisting of: silicon, silicon carbide, gallium arsenide, gallium nitride.

At S120, oxide 211 is removed from the substrate 210. For example, the removal can be achieved by polishing the substrate 210. In some embodiments, the substrate 210 is set into a plasma chamber. The plasma chamber can enclose a plasma. In the plasma chamber, the oxide 211 can then be removed from the substrate 210. In particular, the oxide 211 can be removed from the surface 212 of the substrate 210 that faces open space in the chamber by exposing the surface 212 to the plasma. At least one effect can be that semiconductor device to be manufactured becomes more reliable. In particular, as can be seen with reference to FIG. 2B, absent the oxide 211, a transition at a boundary surface 212 of the substrate 210 to another substance layer can be well defined.

At S130, the substrate 210 is exposed to a second plasma. It should be understood that in some embodiments, the first plasma is also the second plasma. In some embodiments, the second plasma comprises an inert species. For example, the plasma can comprise helium and/or argon. In some embodiments, the plasma includes one or more of group of ingredients consisting of: nitrogen ions, carbon ions, methane, ethylene, ethene. At least one effect can be that the plasma deposits plasma particles on the substrate 210 whereby a protective substance layer 220 builds on the substrate. Thus, in some embodiments, the protective substance layers builds directly on the substrate. In some embodiments, removing the oxide from the surface of the substrate 210 and exposing the surface 210 to the plasma are performed in one step.

In some embodiments, the method comprises providing a gas in plasma chamber. The gas can be exposed to an alternating electric field. At least one effect can be that some of the particles of the plasma are stripped of one or more electrons so as to become charged particles, i.e., ions that thus form the plasma.

In some embodiments, some of the plasma's ingredients, i.e., some of the particles comprised in the plasma chemically react with substrate material or other material. Accordingly, in some embodiments, the protective substance layer 220 formed on the substrate 210 comprises one or more of a group of materials consisting of: crystalline silicon carbide, amorphous silicon carbide, nitride.

In some embodiments, the method comprises heating the substrate to a temperature of from 300° C. to 500° C. In some embodiments, the method comprises heating the substrate to a temperature of from 350° C. to 450° C. In some embodiments, the method comprises heating the substrate to a temperature of from 390° C. to 410° C. At least one effect can be that the oxide-removal and/or the deposition process can be completed particularly efficiently.

In some embodiments, the plasma is held to a pressure of less than or equal to atmospheric pressure. At least one effect can be that the deposition process can be controlled with a level of precision that is beneficial to depositing so much substance as is required to form the desired protective layer 220 on the substrate 210. In some embodiments, the plasma is held to a pressure in a range of from 0.1 kPa to 2 kPa. For example, the plasma is held to a pressure in a range of from 1 kPa to 1.2 kPa.

In some embodiments, the step exposing the substrate 210 to the plasma (S130) comprises providing an alternating electric field in the plasma. At least one effect can be that the ions are accelerated by the alternate electric field. Therefore, some ions may hit hard the surface of the substrate that is exposed to the plasma. Thus, the surface of the substrate 210 is heated, atoms of the substrate 210 may react with plasma particles, and the ion may be captured on the surface of the substrate. In some embodiments the electric field alternates at a radio frequency. In some embodiments the the electric field alternates at a frequency of from 10 MHz to 30 MHz. For example, the method comprises to have the electric field alternate at a frequency of from 13.5 MHz to 13.6 MHz such as having the electric field alternate at a frequency of 13.56 MHz. At least one effect can be that the plasma deposition process can be completed particularly efficiently with one or more of the ingredients stated above.

At S140 a structure layer 230 is provided on the protective layer 220. At least one effect of the structure layer 230 can be to provide functionality to the semiconductor device 200.

FIG. 2C is a schematic diagram schematically illustrating a cross-sectional partial view of the exemplary semiconductor device 200 according to some embodiments. The semiconductor device 200 comprises the substrate 210 and, disposed above the substrate 210 at the boundary surface 212, the protective substance layer 220. In some embodiments, the protective substance layer 220 is deposited in situ on the substrate 210. At least one effect of the protective substance layer can be to ensure a high breakthrough voltage.

In some embodiments, the semiconductor device 200 comprises at least one device structure layer 230 configured to provide functionality to the semiconductor device 200 as will be explained in more detail below. In some embodiments, the device structure layer 230 is formed on the protective substance layer 220. However, in some embodiments (not shown), the device structure layer can also be formed below the protective substance layer.

The semiconductor device 200 may comprise various types of active and passive devices such as diodes, transistors, thyristors, capacitors, inductors, resistors, optoelectronic devices, sensors, micro-electro-mechanical systems, and others. In various embodiments, the semiconductor device 200 may comprise an integrated circuit or a single electrical, mechanical or electro-mechanical element. Also, the semiconductor device 200 can be a mircroelectrical-mechanical system (MEMS) device, power transistor, logic chip, a memory chip, an analog chip, a mixed signal chip, and combinations thereof such as a system on chip, or other suitable types of devices.

In some embodiments, the semiconductor device 200 is a power semiconductor device. At least one effect can be that the semiconductor device 200 can operate at high voltages. Another effect can be that the semiconductor device 200 can operate with high currents.

In some embodiments, the substrate 210 is crystalline. In some embodiments, the crystalline substrate 210 comprises one or more of a group consisting of: silicon, silicon carbide, gallium arsenide, gallium nitride.

In some embodiments, the protective substance layer 220 comprises one or more of a group consisting of: crystalline silicon carbide, amorphous silicon carbide, nitride.

In some embodiments, the protective substance layer 220 has a density of from 2 to 3 g/cm\hat{ }3 (hex.).

In some embodiments, the protective substance layer 220 mostly comprises silicon carbide and has a density of at least 2.2 g/cm\hat{ }3 (hex.).

In some embodiments, the protective substance layer 220 mostly comprises silicon nitride and has a density of at least 2.2 g/cm\hat{ }3 (hex.).

In some embodiments, the protective substance layer 220 has a polymer content of less than 1 percentage by weight (wt %). In some embodiments, the protective substance layer 220 has a polymer content of less than 1 per mille weight. At least one effect can be that a protection against impurity diffusion is particularly strong.

In some embodiments, the protective substance layer 220 has a break-through voltage of more than 1 kilovolt per micron. In some embodiments, the protective substance layer has a break-through voltage of more than 10 kilovolt per micron.

In some embodiments, the protective substance layer 220 has a hardness y [GPa] versus compressive stress x [GPa] characteristic in a range of +/−0.5 GPa, preferably in a range of +/−0.2 GPa, about a line according to the expression y=−15.375 x+10.825.

In some embodiments, an absorption spectrum of the substance layer 220 in a wavelength range of from 3350 nm to 2350 nm is essentially a linear function of wavelength.

In some embodiments, an absorption peak in a spectrum of the dielectric layer in a wavelength range of from 2350 nm to 1850 nm has an integral breadth of more than 50 nm, preferably of more than 60 nm, wherein the integral breadth is defined as the ratio of peak area/peak maximum, and wherein the peak area is an area under a curve of the absorption spectrum (background subtracted).

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein.

In some instances, well-known features are omitted or simplified to clarify the description of the exemplary implementations.

As used herein, the word ‘exemplary’ means serving as an example, instance, or illustration. Any aspect or design described herein as ‘exemplary’ is not necessarily to be construed as preferred or advantageous over other aspects or designs. Rather, use of the word exemplary is intended to present concepts and techniques in a concrete fashion. The term ‘techniques,’ for instance, may refer to one or more devices, apparatuses, systems, methods, articles of manufacture, and/or computer-readable instructions as indicated by the context described herein.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for manufacturing a high-voltage semiconductor device, the method comprising:
exposing a semiconductor substrate to a plasma to form a protective substance layer on the semiconductor substrate,
wherein the plasma includes an inert species,
wherein the plasma includes one or more selected from the group consisting of: a hydrogen species; a carbon species; methane; ethylene; and ethene.

2. The method of claim 1, wherein the inert species includes one or more selected from the group consisting of: a helium species and an argon species.

3. The method of claim 1, further comprising:
heating the semiconductor substrate to a temperature of from 300° C. to 500° C.

4. The method of claim 1, further comprising:
providing an alternating electric field; and
exposing a gas to the alternating electric field,
wherein the electric field alternates at a radio frequency.

5. The method of claim 1, wherein the plasma is held to a pressure of less than or equal to atmospheric pressure.

6. The method of claim 1, further comprising:
removing an oxide from the semiconductor substrate.

7. The method of claim 6, wherein removing the oxide from the semiconductor substrate comprises:
setting the semiconductor substrate in a chamber; and
before exposing the semiconductor substrate to the plasma, removing the oxide from the semiconductor substrate while the semiconductor substrate is in the chamber.

8. A semiconductor device, comprising:
a semiconductor substrate; and
a protective substance layer on the semiconductor substrate, the protective substance layer comprises crystalline silicon carbide and/or amorphous silicon carbide.

9. The semiconductor device of claim 8, further comprising a device structure layer on the protective substance layer.

10. The semiconductor device of claim 9, wherein the protective substance layer is deposited in situ on the semiconductor substrate.

11. The semiconductor device of claim 8, wherein the protective substance layer has a density of from 2 to 3 g/cm\hat{ }3 (hex.).

12. The semiconductor device of claim 11, wherein the protective substance layer mostly comprises silicon carbide and has a density of at least 2.2 g/cm\hat{ }3 (hex.).

13. The semiconductor device of claim 8, wherein the protective substance layer has a polymer content of less than 1 percentage by weight (wt %).

14. The semiconductor device of claim 8, wherein the protective substance layer has a break-through voltage of more than 1 kilovolt/micron.

15. The semiconductor device of claim 8, wherein the protective substance layer has a hardness y [GPa] versus compressive stress x [GPa] characteristic in a range of +/−0.5 GPa about a line according to the expression y=−15.375 x+10.825.

16. The semiconductor device of claim 8, wherein an absorption spectrum of the protective substance layer in a wavelength range of from 3350 nm to 2350 nm is essentially a linear function of wavelength.

17. The semiconductor device of claim 8, wherein an absorption peak in a spectrum of the protective substance layer in a wavelength range of from 2350 nm to 1850 nm has an integral breadth of more than 50 nm.

18. The semiconductor device of claim 8, wherein the semiconductor substrate is crystalline.

19. The semiconductor device of claim 18, wherein the crystalline semiconductor substrate comprises one or more selected from the group consisting of: silicon, silicon carbide, gallium arsenide, gallium nitride.
